(19) United States
(12) Patent Application Publication
(10) Pub. No.: US 2022/0217852 A1
(43) Pub. Date: Jul. 7, 2022

(54) PROTECTIVE SHELL AND ELECTRONIC DEVICE WITH THE PROTECTIVE SHELL

(71) Applicant: Chicony Power Technology Co., Ltd., New Taipei City (TW)

(72) Inventor: Yu-Jan Lin, New Taipei City (TW)

(21) Appl. No.: 17/301,286

(22) Filed: Mar. 30, 2021

(30) Foreign Application Priority Data
Jan. 4, 2021 (TW) 1 10100184

(51) Int. Cl. H05K 5/00

(52) U.S. Cl. CPC H05K 5/0004

(57) ABSTRACT

A protective shell includes a first shell and a second shell. The first shell includes a first ring-shaped retaining wall and a resisting portion. The first ring-shaped retaining wall has a first notch. The resisting portion is located inside the first ring-shaped retaining wall and adjacent to the first notch. A height of the resisting portion is greater than that of the first ring-shaped retaining wall. The second shell includes a second ring-shaped retaining wall. The second ring-shaped retaining wall has a second notch, and the first notch corresponds to the second notch. The first shell is combined with the second shell to form an accommodating space. With the above-mentioned design of the first shell and the second shell, the drop-proof ability of electronic devices can be effectively improved.

### CROSS-REFERENCE TO RELATED APPLICATION

This non-provisional application claims priority under 35 U.S.C. § 119(a) to Patent Application No. 110100184 in Taiwan, R.O.C. on Jan. 4, 2021, the entire contents of which are hereby incorporated by reference.

### BACKGROUND

### Technical Field

The present invention relates to a protective shell, and in particular, to a drop-proof protective shell and an electronic device with the protective shell.

### Related Art

Electronic devices such as a power supply, a connector, or a hard disk are commonly used in modern society. Generally, when the electronic device is impacted, an internal circuit board is likely to collide with an upper cover or a lower cover, causing fracture of the upper cover or the lower cover to break, or fracture of a position where the upper cover is engaged with the lower cover. Therefore, people have relative demands for a drop-proof function of electronic devices.

Conventionally, an overall drop-proof capability of an electronic device is strengthened by increasing a thickness of a shell. However, increasing the thickness of the shell does not necessarily improve the drop-proof capability of the electronic device, and is likely to increase manufacturing costs.

In view of this, the inventors finally complete a protective shell and an electronic device with the protective shell of the present invention by making improvements through study for deficiencies of a conventional technology, which can effectively improve the drop-proof performance and overcome the deficiencies of the conventional technology.

### SUMMARY

The present invention is mainly intended to provide a drop-proof protective shell and an electronic device with the protective shell, to improve a drop-proof capability of the electronic device.

In order to achieve the foregoing objective, the present invention provides an embodiment of an electronic device. The electronic device includes a first shell, a second shell, and a circuit board. The first shell includes a first ring-shaped retaining wall and a resisting portion. An upper end face of the first ring-shaped retaining wall has a butting portion, and the first ring-shaped retaining wall has a first notch. The resisting portion is located inside the first ring-shaped retaining wall and adjacent to the first notch, and a height of the resisting portion is greater than that of the first ring-shaped retaining wall. The second shell includes a second ring-shaped retaining wall. An upper end face of the second ring-shaped retaining wall has a matching element, and the second ring-shaped retaining wall has a second notch. The first notch corresponds to the second notch, and the butting portion is engaged with the matching element to form an accommodating space between the first shell and the second shell. The circuit board is located in the accommodating space, and the resisting portion is adjacent to the circuit board.

According to the above electronic device, in an embodiment, the resisting portion is adjacent to the second ring-shaped retaining wall.

According to the above electronic device, in an embodiment, the resisting portion includes a body and a protrusion. The body is connected to one side of the protrusion, the protrusion extends toward a side surface of the circuit board, and the protrusion has a resisting surface. A distance between the resisting surface and the circuit board is smaller than a distance between the body and the circuit board.

According to the above electronic device, in an embodiment, the resisting portion further includes a supporting arm connected to another side of the protrusion. The supporting arm extends toward the side surface of the circuit board and protrudes from a surface of the protrusion.

According to the above electronic device, in an embodiment, the first shell further includes a protruding rib and a bottom plate. The first ring-shaped retaining wall and the resisting portion are connected to the bottom plate, and the protruding rib is attached to the resisting portion. One end of the protruding rib is connected to the bottom plate, and another end of the protruding rib extends to an inner side of the second ring-shaped retaining wall.

According to the above electronic device, in an embodiment, the first shell further includes a supporting wall. The supporting wall is attached to the body, and one end of the supporting wall is connected to the bottom plate.

According to the above electronic device, in an embodiment, the resisting portion includes a first resisting wall and a second resisting wall. The first resisting wall is connected to an inner side of the first ring-shaped retaining wall, and the first resisting wall is spaced from the second resisting wall. The second resisting wall includes a resisting wall portion and a bulge portion. The bulge portion is connected to the resisting wall portion, extends toward a side surface of the circuit board, and has a resisting surface. A distance between the resisting surface and the circuit board is smaller than a distance between the resisting wall portion and the circuit board.

According to the above electronic device, in an embodiment, the resisting portion further includes a partition wall located between the first resisting wall and the second resisting wall and connected to the first resisting wall and the second resisting wall.

According to the above electronic device, in an embodiment, the first shell further includes a reinforcing wall and a bottom plate. The reinforcing wall extends toward the resisting portion from the bottom plate and is connected to the resisting portion.

According to the above electronic device, in an embodiment, the electronic device further includes a connecting assembly. When the first shell and the second shell are engaged with each other, the first notch and the second notch form an opening. The connecting assembly is located in the opening and connected to the circuit board.

The present invention further provides an embodiment of a protective shell. The protective shell includes a first shell and a second shell.

The first shell includes a first ring-shaped retaining wall and a resisting portion. An upper end face of the first ring-shaped retaining wall has a butting portion, and the first ring-shaped retaining wall has a first notch. The resisting portion is located inside the first ring-shaped retaining wall and adjacent to the first notch, and a height of the resisting portion is greater than that of the first ring-shaped retaining wall. The second shell includes a second ring-shaped retaining wall. An upper end face of the second ring-shaped retaining wall has a matching element, and the second ring-shaped retaining wall has a second notch. The first notch corresponds to the second notch, and the butting portion is engaged with the matching element to form an accommodating space between the first shell and the second shell.

According to the above protective shell, in an embodiment, the resisting portion is adjacent to the second ring-shaped retaining wall.

According to the above protective shell, in an embodiment, the resisting portion includes a body and a protrusion. The body is connected to one side of the protrusion. The protrusion protrudes from a surface of the body, and the protrusion has a resisting surface.

According to the above protective shell, in an embodiment, the resisting portion further includes a supporting arm connected to another side of the protrusion and protrudes from a surface of the protrusion.

According to the above protective shell, in an embodiment, the first shell further includes a protruding rib and a bottom plate. The first ring-shaped retaining wall and the resisting portion are connected to the bottom plate, and the protruding rib is attached to the resisting portion. One end of the protruding rib is connected to the bottom plate, and another end of the protruding rib extends to an inner side of the second ring-shaped retaining wall.

According to the above protective shell, in an embodiment, the first shell further includes a supporting wall. The supporting wall is attached to the body, and one end of the supporting wall is connected to the bottom plate.

According to the above protective shell, in an embodiment, the resisting portion includes a first resisting wall and a second resisting wall. The first resisting wall is connected to the inner side of the first ring-shaped retaining wall, and the first resisting wall is spaced from the second resisting wall. The second resisting wall includes a resisting wall portion and a bulge portion. The bulge portion is connected to the resisting wall portion, protrudes from a surface of the resisting wall portion, and has a resisting surface.

According to the above protective shell, in an embodiment, the resisting portion includes a partition wall located between the first resisting wall and the second resisting wall and connected to the first resisting wall and the second resisting wall.

According to the above protective shell, in an embodiment, the first shell further includes a reinforcing wall and a bottom plate. The reinforcing wall extends toward the resisting portion from the bottom plate and is connected to the resisting portion.

The electronic device according to one or more embodiments of the present invention has the protective shell (the first shell and the second shell), and the resisting portion of the first shell is adjacent to the circuit board. When the electronic device drops with a side edge toward the ground, the resisting portion effectively supports the circuit board to prevent the circuit board from laterally colliding with the second shell, to prevent fracture of the second shell or a position where the first shell is engaged with the second shell. In an embodiment, the structure of the protective shell has the drop-proof capability of more than 10 times a shell structure of the prior art. Not only strength of the protective shell is increased, but also the accommodating space is increased because the protective shell is thinner than that of the prior art, facilitating a larger degree of thinness and miniaturization of electronic devices. In addition, manufacturing costs can be reduced. Therefore, the problems in the prior art can be effectively alleviated.

### BRIEF DESCRIPTION OF THE DRAWINGS

FIG. 1 is a schematic exploded view (I) of a first embodiment of an electronic device according to the present invention.

FIG. 2 is a schematic exploded view (II) of a first embodiment of an electronic device according to the present invention.

FIG. 3 is a partial enlarged view of a first shell in the embodiment shown in FIG. 2.

FIG. 4 is a schematic diagram of a relationship between a first shell and a circuit board in the embodiment shown in FIG. 2.

FIG. 5 is a schematic exploded view (I) of a second embodiment of an electronic device according to the present invention.

FIG. 6 is a schematic exploded view (II) of a second embodiment of an electronic device according to the present invention.

FIG. 7 is a partial enlarged view of a first shell according to the embodiment shown in FIG. 6.

FIG. 8 is a schematic diagram of a relationship between a first shell and a circuit board in the embodiment shown in FIG. 6.

FIG. 9 is a schematic exploded view (I) of a third embodiment of an electronic device according to the present invention.

FIG. 10 is a schematic exploded view (II) of a third embodiment of an electronic device according to the present invention.

FIG. 11 is a partial enlarged view of a first shell in the embodiment shown in FIG. 10.

FIG. 12 is a schematic diagram of a relationship between a first shell and a circuit board in the embodiment shown in FIG. 10.

FIG. 13 is a schematic exploded view (I) of a fourth embodiment of an electronic device according to the present invention.

FIG. 14 is a schematic exploded view (II) of a fourth embodiment of an electronic device according to the present invention.

FIG. 15 is a partial enlarged view of a first shell in the embodiment shown in FIG. 14.

FIG. 16 is a schematic diagram of a relationship between a first shell and a circuit board in the embodiment shown in FIG. 14.

FIG. 17 is a schematic diagram of an exterior of an embodiment of a protective shell according to the present invention.

FIG. 18 is a schematic exploded view of a first embodiment of a protective shell according to the present invention.

FIG. 19 is a schematic exploded view of a second embodiment of a protective shell according to the present invention.

FIG. 20 is a schematic exploded view of a third embodiment of a protective shell according to the present invention.

FIG. 21 is a schematic exploded view of a fourth embodiment of a protective shell according to the present invention.

### DETAILED DESCRIPTION

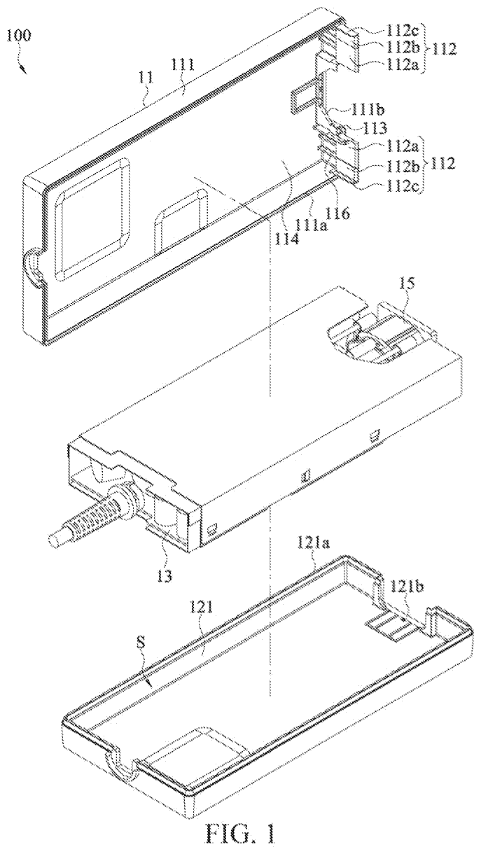

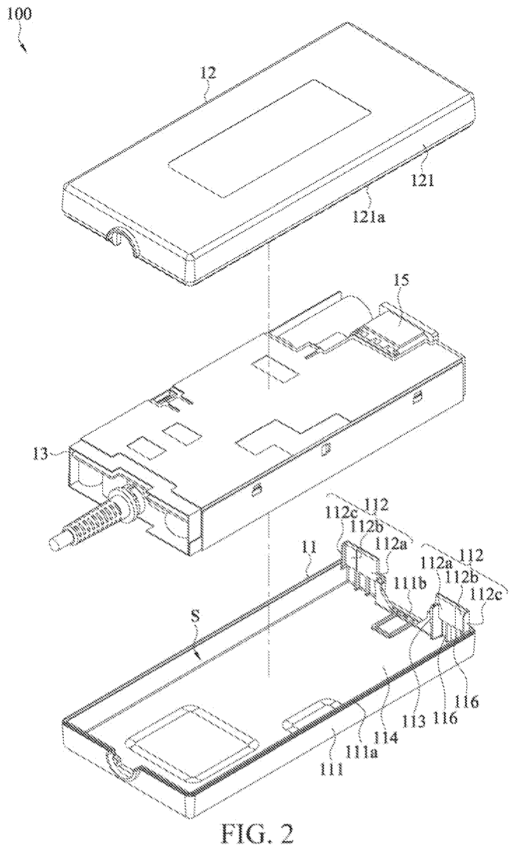

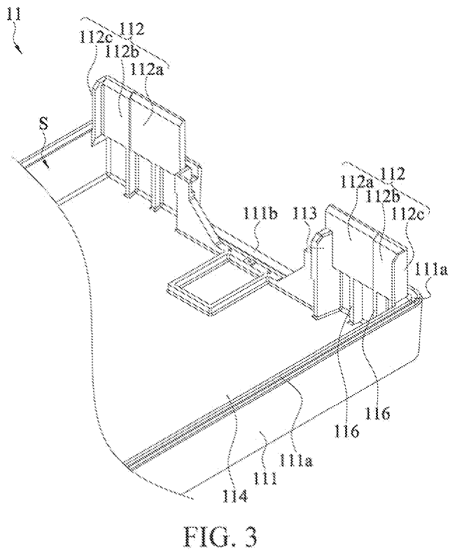

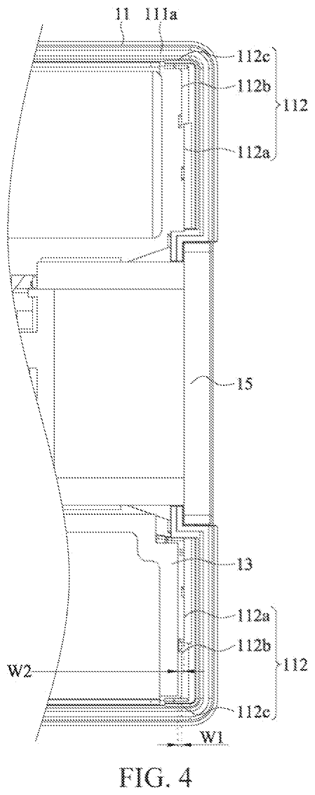

Referring to FIG. 1 to FIG. 4, FIG. 1 and FIG. 2 are respectively schematic exploded views (I) and (II) of a first embodiment of an electronic device 100 according to the present invention. FIG. 1 and FIG. 2 are shown in different perspectives. FIG. 3 is a partial enlarged view of a first shell 11 in the embodiment shown in FIG. 2. FIG. 4 is a schematic diagram of a relationship between the first shell 11 and a circuit board 13 in the embodiment shown in FIG. 2.

The electronic device 100 includes a first shell 11, a second shell 12, and a circuit board 13. The electronic device 100 may be a connector or a power supply.

The first shell 11 includes a first ring-shaped retaining wall 111 and a resisting portion 112. An upper end face of the first ring-shaped retaining wall 111 has a butting portion 111a. In this embodiment, the butting portion 111a is a groove. The first ring-shaped retaining wall 111 has a first notch 111b. As shown in FIG. 1 to FIG. 3, the first notch 111b is substantially U-shaped. The resisting portion 112 is located inside the first ring-shaped retaining wall 111 and adjacent to the first notch 111b. A height of the resisting portion 112 is greater than that of the first ring-shaped retaining wall 111. The first shell 11 and the second shell 12 may be made of plastic or metal (alloy), which is not limited in the present invention.

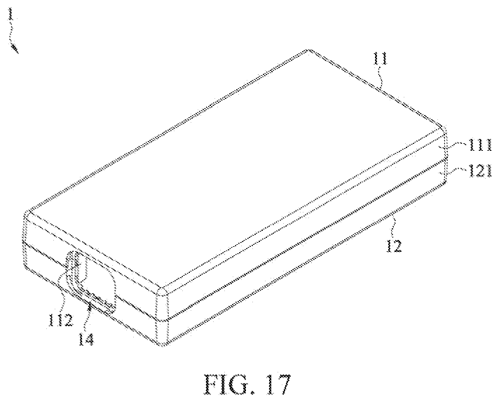

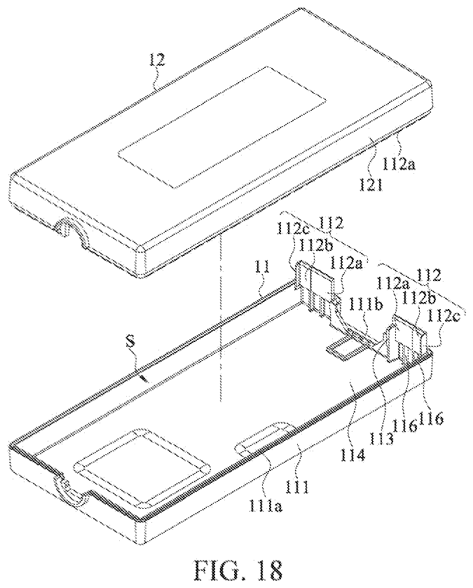

The second shell 12 includes a second ring-shaped retaining wall 121. An upper end face of the second ring-shaped retaining wall 121 has a matching element 121a that may be engaged with the above butting portion 111a. In the first embodiment, the matching element 121a is a protruding structure that may be snap-fitted into the groove. Certainly, the present invention is not limited thereto. In some embodiments, the butting portion 111a may be a protruding structure, and the matching element 121a is a groove. The second ring-shaped retaining wall 121 has a second notch 121b, which is also substantially U-shaped. The first notch 111b corresponds to the second notch 121b. When the butting portion 111a is engaged with the matching element 121a, the first notch 111b and the second notch 121b form an opening 14 (see FIG. 17), and an accommodating space S (see FIG. 18) is formed between the first shell 11 and the second shell 12. A circuit board 13, a capacitor, and other electronic assemblies may be disposed in the accommodating space S.

The circuit board 13 is located in the accommodating space S, and the resisting portion 112 is adjacent to the circuit board 13. In some embodiments, the first shell 11 and the second shell 12 are engaged with each other through ultrasonic welding. However, the present invention is not limited thereto. By virtue of the structure, when the electronic device 100 drops with a side edge toward the ground, the resisting portion 112 may support the circuit board 13 to protect the circuit board 13, so as to prevent the circuit board 13 from colliding with the second shell 12, thereby preventing the second shell 12 from fracturing as a result of the collision. In some embodiments, a gap between the resisting portion 112 and the circuit board 13 ranges from 0.2 mm to 0.5 mm.

In some embodiments, heights of the first shell 11 and the second shell 12 are determined according to requirements of a user, and the resisting portion 112 is disposed adjacent to the second ring-shaped retaining wall 121. This is not limited in the present invention.

As shown in FIG. 1 to FIG. 4, there are two resisting portions 112 respectively located on both sides of the first notch 111b. The resisting portion 112 includes a body 112a and a protrusion 112b. The body 112a is connected to one side of the protrusion 112b, the protrusion 112b extends toward a side surface of the circuit board 13, and the protrusion 112b has a resisting surface. A distance W1 between the resisting surface and the circuit board 13 is smaller than a distance W2 (shown in FIG. 4) between the body 112a and the circuit board 13. By virtue of the structural design, fracture of the second shell 12 caused by lateral collision of the circuit board 13 with the second shell 12 can be effectively prevented when the electronic device 100 drops. In addition, in this embodiment, the resisting portion 112 further includes a supporting arm 112c connected to another side of the protrusion 112b. The supporting arm 112c extends toward the side surface of the circuit board 13 and protrudes from a surface of the protrusion 112b, and the supporting arm 112c can reinforce a side edge of the first ring-shaped retaining wall 111.

As shown in FIG. 2 to FIG. 3, the first shell 11 further includes a protruding rib 113 and a bottom plate 114. The first ring-shaped retaining wall 111 and the resisting portion 112 are connected to the bottom plate 114. The protruding rib 113 is attached to the resisting portion 112. One end of the protruding rib 113 is connected to the bottom plate 114, and another end of the protruding rib 113 extends to an inner side of the second ring-shaped retaining wall 121. The protruding rib 113 is disposed for reinforcing the side edge of the first ring-shaped retaining wall 111.

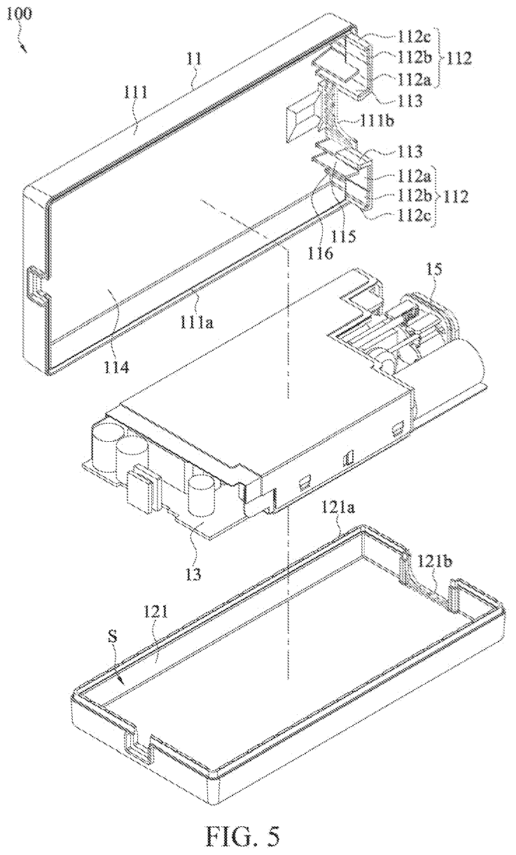

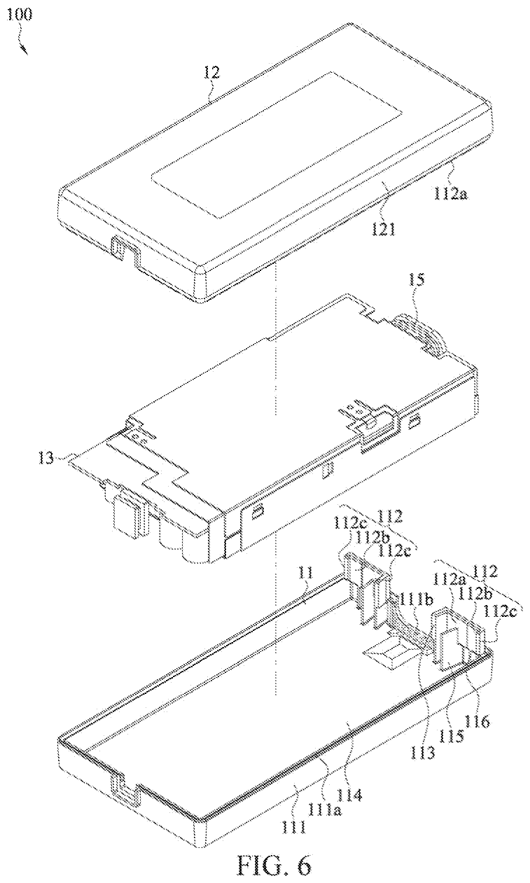

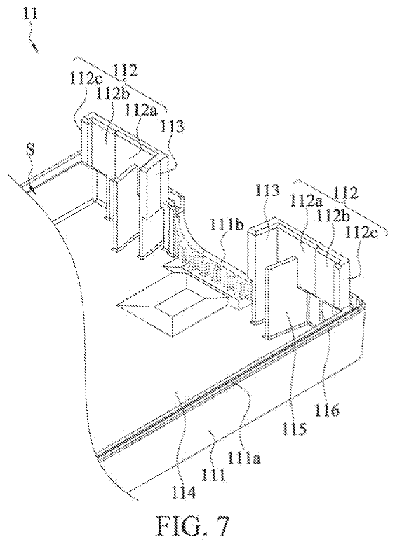

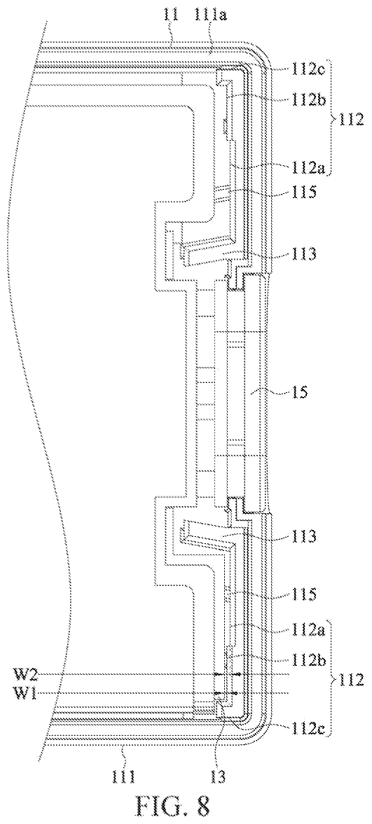

Referring to FIG. 5 to FIG. 8, FIG. 5 and FIG. 6 are respectively schematic exploded views (I) and (II) of a second embodiment of an electronic device 100 according to the present invention. FIG. 5 and FIG. 6 are shown in different perspectives. FIG. 7 is a partial enlarged view of a first shell 11 in the embodiment shown in FIG. 6. FIG. 8 is a schematic diagram of a relationship between the first shell 11 and a circuit board 13 in the embodiment shown in FIG. 6.

A difference between this embodiment and the first embodiment is that the first shell 11 further includes a supporting wall 115. The supporting wall 115 is attached to the body 112a, and one end of the supporting wall 115 is connected to the bottom plate 114. The supporting wall 115 is disposed for reinforcing the side edge of the first ring-shaped retaining wall 111 and enhancing a drop-proof capability.

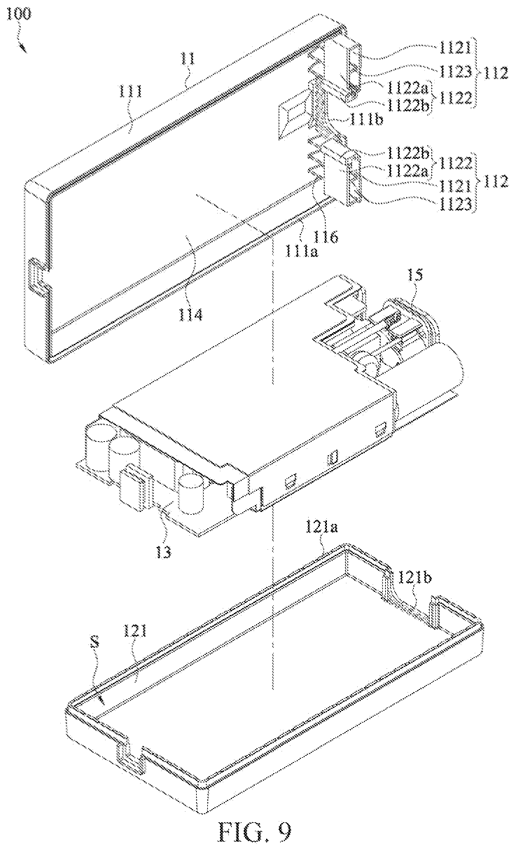

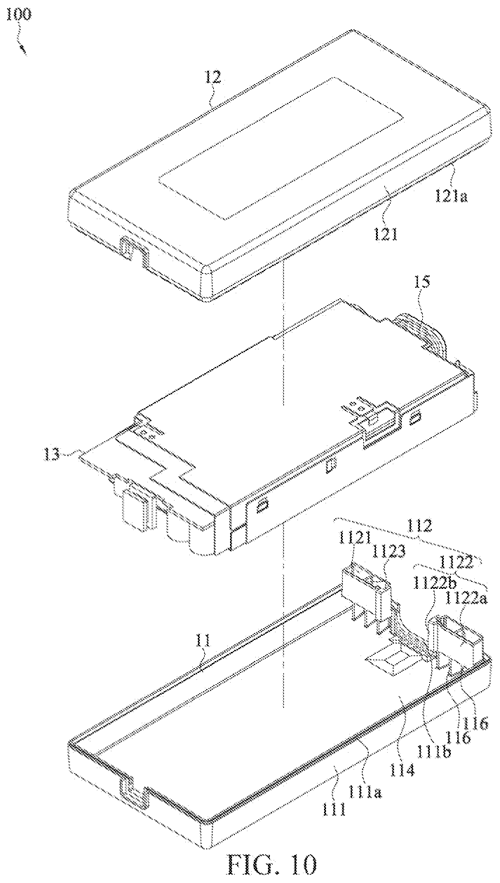

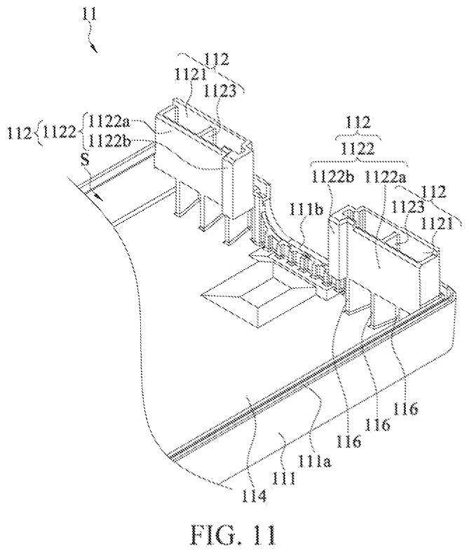

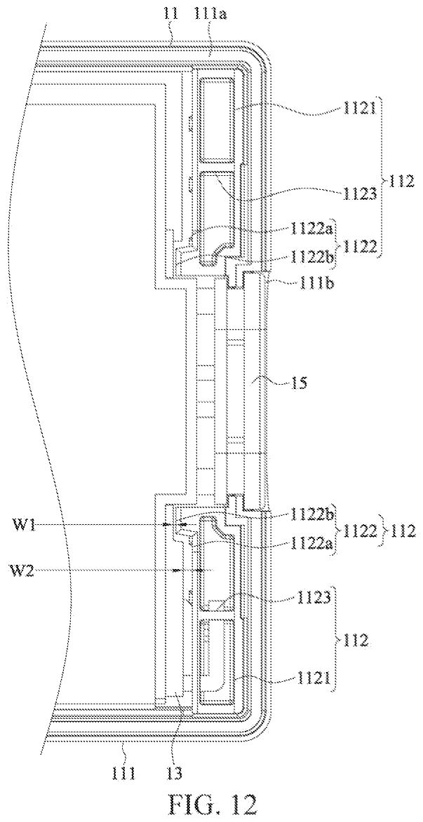

Referring to FIG. 9 to FIG. 12, FIG. 9 and FIG. 10 are respectively schematic exploded views (I) and (II) of a third embodiment of an electronic device 100 according to the present invention. FIG. 9 and FIG. 10 are shown in different perspectives. FIG. 11 is a partial enlarged view of a first shell 11 in the embodiment shown in FIG. 10. FIG. 12 is a schematic diagram of a relationship between the first shell 11 and a circuit board 13 in the embodiment shown in FIG. 10.

In this embodiment, there are two resisting portions 112 disposed on both sides of a first notch 111b, and the resisting portions 112 have a form different from that of the above embodiment. The resisting portion 112 includes a first resisting wall 1121 and a second resisting wall 1122. The first resisting wall 1121 is connected to an inner side of the first ring-shaped retaining wall 111, and the first resisting wall 1121 is spaced from the second resisting wall 1122. The second resisting wall 1122 includes a resisting wall portion 1122a and a bulge portion 1122b. The bulge portion 1122b is connected to the resisting wall portion 1122a, the bulge portion 1122b extends toward a side surface of the circuit board 13, and the bulge portion 1122b has a resisting surface. A distance W1 between the resisting surface and the circuit board 13 is smaller than a distance W2 between the resisting wall portion 1122a and the circuit board 13. Similarly, the resisting portion 112 is disposed for the following purpose. When the electronic device 100 drops with a side edge (for example, the first notch 111b) toward the ground, the resisting portion 112 may support the circuit board 13 to protect the circuit board 13, so as to prevent the circuit board 13 from colliding with the second shell 12, thereby preventing the second shell 12 from fracturing as a result of the collision.

In addition, in this embodiment, in order to reinforce the overall structure of the resisting portion 112, the resisting portion 112 further includes a partition wall 1123 located between the first resisting wall 1121 and the second resisting wall 1122 and connected to the first resisting wall 1121 and the second resisting wall 1122. In addition, in this embodiment, the first shell 11 further includes a reinforcing wall 116 and a bottom plate 114. The reinforcing wall 116 extends toward the resisting portion 112 from the bottom plate 114 and is connected to the resisting portion 112. The reinforcing wall 116 is disposed for reinforcing the side edge of the first ring-shaped retaining wall 111.

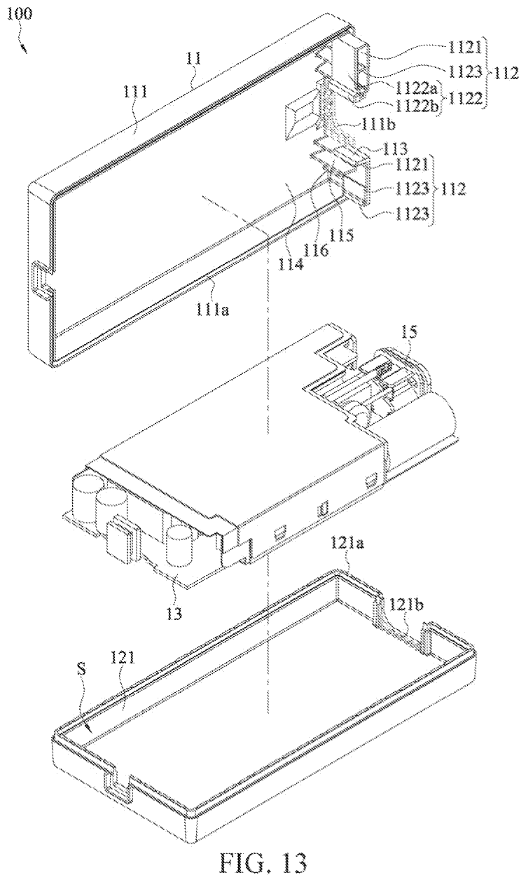

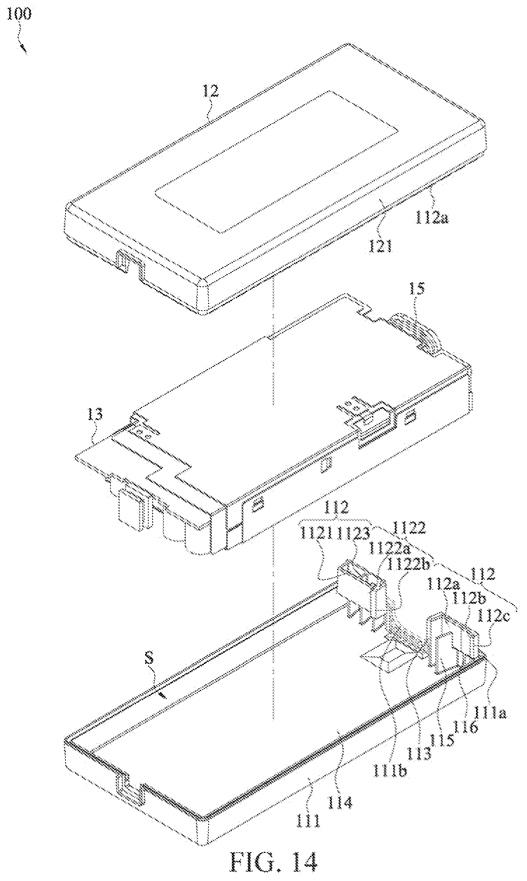

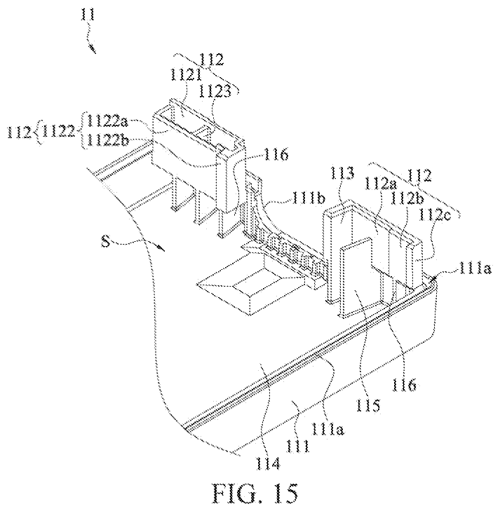

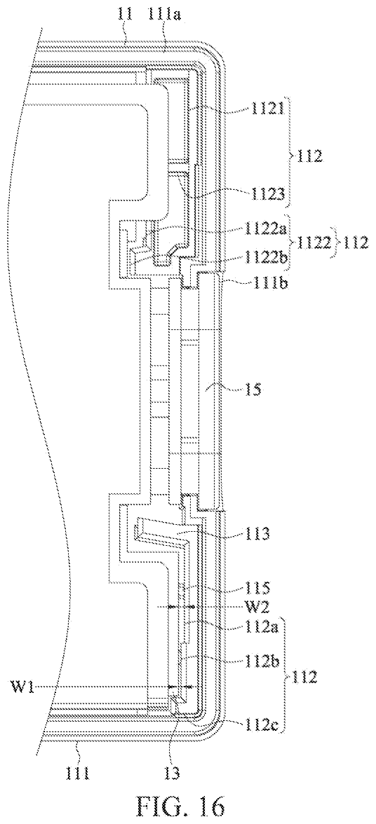

Referring to FIG. 13 to FIG. 16, FIG. 13 and FIG. 14 are respectively schematic exploded views (I) and (II) of a fourth embodiment of an electronic device 100 according to the present invention. FIG. 13 and FIG. 14 are shown in different perspectives. FIG. 15 is a partial enlarged view of a first shell 11 in the embodiment shown in FIG. 14. FIG. 16 is a schematic diagram of a relationship between the first shell 11 and a circuit board 13 in the embodiment shown in FIG. 14.

In the fourth embodiment, there are two resisting portions 112, which are respectively located on opposite sides of the first notch 111b and respectively in the forms of the resisting portions 112 shown in the second embodiment and the third embodiment. For the description of the resisting portion 112, refer to the above description again. Certainly, the first shell 11 may also adopt the resisting portions 112 shown in the first embodiment and the second embodiment or the first embodiment and the third embodiment. In other words, a type of the resisting portion 112 is not limited in the present invention, and the resisting portion 112 is disposed according to requirements (for example, a type of a circuit board 13 that is adopted) of a user. In addition, in the above embodiment, two resisting portions 112 are adopted, which is not limited in the present invention. In some embodiments, only one resisting portion 112 may be disposed by the user, which is located on one side of the first notch 111b and may be adjacent to the first notch 111b or away from the first notch 111b. When the electronic device 100 drops with a side edge (for example, the first notch 111b) toward the ground, the circuit board 13 is supported to prevent the circuit board from colliding with the second shell 12, thereby preventing the second shell 12 from fracturing as a result of the collision.

Referring to FIG. 1 to FIG. 16 again, in the embodiments, the electronic device 100 further includes a connecting assembly 15. When the first shell 11 and the second shell 12 are engaged with each other, the first notch 111b and the second notch 121b form an opening 14, and the connecting assembly 15 is located in the opening 14 and connected to the circuit board 13.

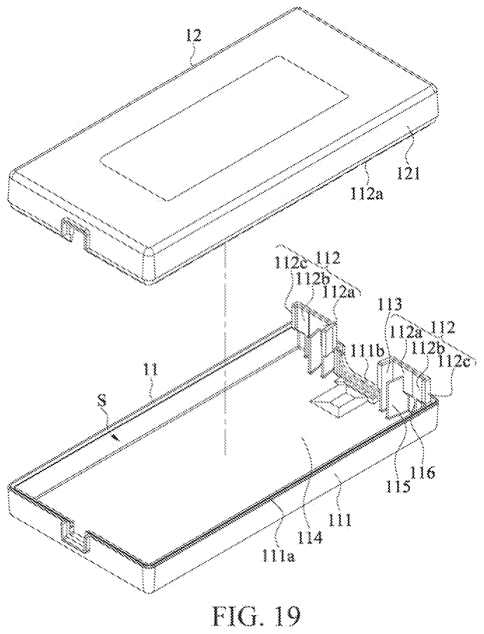

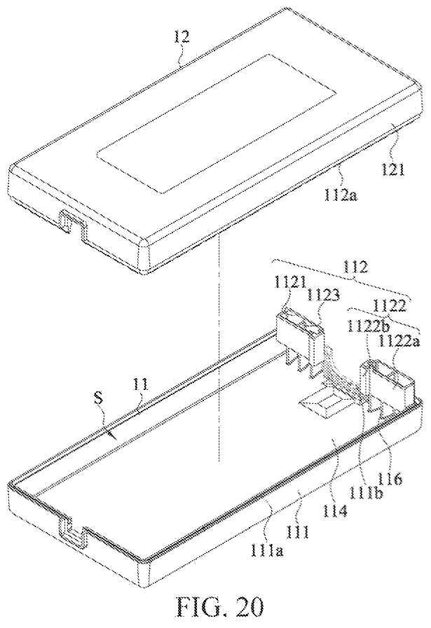

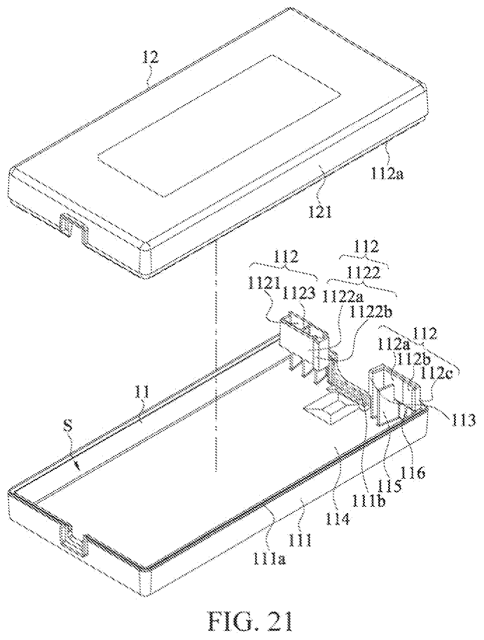

Referring to FIG. 17 to FIG. 21, FIG. 17 is a schematic diagram of an exterior of an embodiment of a protective shell 1 according to the present invention. FIG. 18 to FIG. 21 are respectively schematic exploded views of a first embodiment to a fourth embodiment of the protective shell 1 according to the present invention. The protective shell 1 includes a first shell 11 and a second shell 12. For description of the first shell 11, the resisting portion 112, and the second shell 12, refer to the above description as well as FIG. 1 to FIG. 16. Details are not described herein again.

The protective shell 1 of the present invention may be applied to the electronic device 100 such as a connector or a power supply, which is not limited in the present invention. In some embodiments, the protective shell 1 may be applied to a hard disk.

The electronic device according to one or more embodiments of the present invention has the protective shell (the first shell and the second shell), and the resisting portion of the first shell is adjacent to the circuit board. When the electronic device drops with a side edge toward the ground, the resisting portion effectively supports the circuit board to prevent the circuit board from laterally colliding with the second shell, to prevent fracture of the second shell or a position where the first shell is engaged with the second shell. In an embodiment, the structure of the protective shell has the drop-proof capability of more than 10 times a shell structure of the prior art. Not only strength of the protective shell is increased, but also the accommodating space is increased because the protective shell is thinner than that of the prior art, facilitating a larger degree of thinness and miniaturization of electronic devices. In addition, manufacturing costs can be reduced. Therefore, the problems in the prior art can be effectively alleviated.

What is claimed is:

1. An electronic device, comprising:
a first shell comprising a first ring-shaped retaining wall and a resisting portion, wherein an upper end face of the first ring-shaped retaining wall has a butting portion, the first ring-shaped retaining wall has a first notch, the resisting portion is located inside the first ring-shaped retaining wall and adjacent to the first notch, and a height of the resisting portion is greater than that of the first ring-shaped retaining wall;
a second shell comprising a second ring-shaped retaining wall, wherein an upper end face of the second ring-shaped retaining wall has a matching element, and the second ring-shaped retaining wall has a second notch, wherein the first notch corresponds to the second notch, and the butting portion is engaged with the matching element to form an accommodating space between the first shell and the second shell; and
a circuit board located in the accommodating space, wherein the resisting portion is adjacent to the circuit board.

2. The electronic device according to claim 1, wherein the resisting portion comprises a body and a protrusion, wherein the body is connected to one side of the protrusion, the protrusion extends toward a side surface of the circuit board, the protrusion has a resisting surface, and a distance between the resisting surface and the circuit board is smaller than a distance between the body and the circuit board.

3. The electronic device according to claim 2, wherein the resisting portion further comprises a supporting arm connected to another side of the protrusion, wherein the supporting arm extends toward the side surface of the circuit board and protrudes from a surface of the protrusion.

4. The electronic device according to claim 1, wherein the first shell further comprises a protruding rib and a bottom plate, wherein the first ring-shaped retaining wall and the resisting portion are connected to the bottom plate, the protruding rib is attached to the resisting portion, one end of the protruding rib is connected to the bottom plate, and another end of the protruding rib extends to an inner side of the second ring-shaped retaining wall.

5. The electronic device according to claim 2, wherein the first shell further comprises a protruding rib and a bottom plate, wherein the first ring-shaped retaining wall and the resisting portion are connected to the bottom plate, the protruding rib is attached to the resisting portion, one end of the protruding rib is connected to the bottom plate, and another end of the protruding rib extends to an inner side of the second ring-shaped retaining wall.

6. The electronic device according to claim 3, wherein the first shell further comprises a protruding rib and a bottom plate, wherein the first ring-shaped retaining wall and the resisting portion are connected to the bottom plate, the protruding rib is attached to the resisting portion, one end of the protruding rib is connected to the bottom plate, and another end of the protruding rib extends to an inner side of the second ring-shaped retaining wall.

7. The electronic device according to claim 4, wherein the first shell further comprises a supporting wall, wherein the supporting wall is attached to the body, and one end of the supporting wall is connected to the bottom plate.

8. The electronic device according to claim 1, wherein the resisting portion comprises a first resisting wall and a second resisting wall, wherein the first resisting wall is connected to an inner side of the first ring-shaped retaining wall, the first resisting wall is spaced from the second resisting wall, the second resisting wall comprises a resisting wall portion and a bulge portion, wherein the bulge portion is connected to the resisting wall portion, extends toward a side surface of the circuit board, and has a resisting surface, and a distance between the resisting surface and the circuit board is smaller than a distance between the resisting wall portion and the circuit board.

9. The electronic device according to claim 8, wherein the resisting portion further comprises a partition wall located between the first resisting wall and the second resisting wall and connected to the first resisting wall and the second resisting wall.

10. The electronic device according to claim 1, wherein the first shell further comprises a reinforcing wall and a bottom plate, wherein the reinforcing wall extends toward the resisting portion from the bottom plate and is connected to the resisting portion.

11. A protective shell, comprising:
a first shell comprising a first ring-shaped retaining wall and a resisting portion, wherein an upper end face of the first ring-shaped retaining wall has a butting portion, the first ring-shaped retaining wall has a first notch, the resisting portion is located inside the first ring-shaped retaining wall and adjacent to the first notch, and a height of the resisting portion is greater than that of the first ring-shaped retaining wall; and
a second shell comprising a second ring-shaped retaining wall, wherein an upper end face of the second ring-shaped retaining wall has a matching element, and the second ring-shaped retaining wall has a second notch, wherein the first notch corresponds to the second notch, and the butting portion is engaged with the matching element to form an accommodating space between the first shell and the second shell.

12. The protective shell according to claim 11, wherein the resisting portion comprises a body and a protrusion, wherein the body is connected to one side of the protrusion, and the protrusion protrudes from a surface of the body, and having a resisting surface.

13. The protective shell according to claim 12, wherein the resisting portion further comprises a supporting arm connected to another side of the protrusion and protrudes from the surface of the protrusion.

14. The protective shell according to claim 11, wherein the first shell further comprises a protruding rib and a bottom plate, wherein the first ring-shaped retaining wall and the resisting portion are connected to the bottom plate, the protruding rib is attached to the resisting portion, one end of the protruding rib is connected to the bottom plate, and another end of the protruding rib extends to an inner side of the second ring-shaped retaining wall.

15. The protective shell according to claim 12, wherein the first shell further comprises a protruding rib and a bottom plate, wherein the first ring-shaped retaining wall and the resisting portion are connected to the bottom plate, the protruding rib is attached to the resisting portion, one end of the protruding rib is connected to the bottom plate, and another end of the protruding rib extends to an inner side of the second ring-shaped retaining wall.

16. The protective shell according to claim 13, wherein the first shell further comprises a protruding rib and a bottom plate, wherein the first ring-shaped retaining wall and the resisting portion are connected to the bottom plate, the protruding rib is attached to the resisting portion, one end of the protruding rib is connected to the bottom plate, and another end of the protruding rib extends to an inner side of the second ring-shaped retaining wall.

17. The protective shell according to claim 14, wherein the first shell further comprises a supporting wall, wherein the supporting wall is attached to the body, and one end of the supporting wall is connected to the bottom plate.

18. The protective shell according to claim 11, wherein the resisting portion comprises a first resisting wall and a second resisting wall, wherein the first resisting wall is connected to an inner side of the first ring-shaped retaining wall, the first resisting wall is spaced from the second resisting wall, and the second resisting wall comprises a resisting wall portion and a bulge portion, wherein the bulge portion is connected to the resisting wall portion, protrudes from a surface of the resisting wall portion, and has a resisting surface.

19. The protective shell according to claim 18, wherein the resisting portion further comprises a partition wall located between the first resisting wall and the second resisting wall and connected to the first resisting wall and the second resisting wall.
